(19) United States
(12) Patent Application Publication
(10) Pub. No.: US 2006/0289896 A1
(43) Pub. Date: Dec. 28, 2006

(54) Semiconductor device and method for fabricating the same

(75) Inventors: Hirotaka Miyamoto, Toyama (JP); Keiichi Murayama, Toyama (JP); Kenichi Miyajima, Toyama (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/348,378

(22) Filed: Feb. 7, 2006

(30) Foreign Application Priority Data
Jun. 28, 2005 (JP) 2005-187522

(51) Int. Cl. H01L 31/00

(52) U.S. Cl. 257/197

(57) ABSTRACT

A semiconductor device has an interconnect layer for providing an electric connection between a base electrode and a base terminal provided on the region of a semi-insulating substrate on which a transistor is not formed. A resistor layer composed of a material different from respective materials composing the base electrode and the interconnect layer is formed on the base electrode and the base electrode and the interconnect layer are connected to each other via the resistor layer.

### BACKGROUND OF THE INVENTION

The present invention relates to a technology for improving the property and reliability of a semiconductor device operating in the RF band.

In recent years, bipolar transistors, especially heterojunction bipolar transistors (HBTs) composed of compound semiconductors, have been used widely as semiconductor components operating in the RF band, which are represented by power amplifiers for mobile phones. The reason for this is that a HBT has such characteristics features that: (1) the HBT, which is a vertical type device, has a higher current driving ability per unit area than a FET (Field Effect Transistor) which has conventionally been the main stream and therefore allows reductions in size and chip area and that; (2) the HBT, which is of a resistance input type (a signal voltage inputted thereto is adjusted with a resistance), enables easier impedance matching than the FET, which is of a capacitance input type (a signal voltage inputted thereto is adjusted with a capacitance), and therefore allows a reduction in chip size even when an MMIC (Microwave Monolithic Integrated Circuit) is produced;

At the present time, there have been growing demands for power amplifiers for mobile phones which are lower in power consumption and higher in output. To satisfy the demands, it is essentially required to provide a higher-output HBT.

However, the HBT has the problem of heat dissipation. Specifically, since the resistance of a semiconductor layer composing the HBT has a negative temperature coefficient, a positive correlation is observed between an emitter-to-base current and a junction temperature (the temperature of an internal junction portion present between the base and emitter of the HBT or between the base and collector thereof). In other words, the resistance of the HBT lowers as the junction temperature increases to increase the emitter-to-base current. Heat generation resulting from the increased emitter-to-base current causes a further increase in junction temperature. The resulting chain linking process may eventually lead to the breakdown of the device in the worst case.

In consideration of the heat-related problem mentioned above and the degradation of the RF property caused by an increased device area, a higher-output HBT is implemented in most cases by connecting a large number of small-size HBTs in parallel, not by increasing the emitter area of a single HBT. A structure obtained by connecting a large number of HBTs in parallel will be termed a HBT array.

In the case of forming the HBT array, it is necessary to give consideration to causing each of the HBT cells to uniformly operate. This is because, when a current is localized to one of the cells in the HBT array, the resistance of the cell lowers to cause further current localization, which may lead to the breakdown of the device.

To cause each of the cells in the HBT array to uniformly operate, there has commonly been used a method which disposes a ballast resistor outside the base of each of the HBT cells and thereby circumvents the non-uniform operation of each of the cells (see Patent Document 1). The method can circumvent the situation in which non-uniform currents flow in the individual cells and effectively prevent the thermal runaway described above.

Each of FIGS. 7A and 7B shows a schematic structure of a conventional HBT in which a ballast resistor is disposed outside each of the HBT cells, of which FIG. 7A is a plan view thereof and FIG. 7B is a cross-sectional view taken along the line C-C′ of FIG. 7A. In FIG. 7A, some of components are not shown.

As shown in FIG. 7B, a subcollector layer 103, a collector layer 104, a base layer 105, and an emitter layer 106 are stacked successively in an ascending order on a semi-insulating GaAs substrate 101. An emitter electrode 107 is formed on the emitter layer 106. A base electrode 108 is formed on the portion of the base layer 105 on which the emitter layer 106 is not provided. A collector electrode 109 is formed on the portion of the subcollector layer 103 on which the collector layer 104 is not provided. The individual semiconductor layers and electrodes described above constitute a HBT cell 112. The HBT cell 112 is surrounded by an isolation region 115 provided in the GaAs substrate 101.

As shown in FIGS. 7A and 7B, a metal interconnect layer 111A for providing an electric connection between the emitter electrode 107 and an emitter terminal (not shown) provided on the region (hereinafter referred to as a transistor external region) of the GaAs substrate 101 in which the HBT cell 112 is not formed is extracted from the emitter electrode 107. In addition, a metal interconnect layer 111B for providing an electric connection between the base electrode 108 and a base terminal (not shown) provided on the transistor external region is extracted from the base electrode 108. Moreover, a metal interconnect layer 111C for providing an electric connection between the collector electrode 109 and a collector terminal (not shown) provided on the transistor external region is extracted from the collector electrode 109.

As described above, a ballast resistor 116 is disposed to intervene the metal interconnect layer 111B electrically connected to the base electrode 108 to cause each of the cells in the HBT array to uniformly operate, as shown in FIG. 7B.
[Patent Document 1] Japanese Laid-Open Patent Publication No. HEI 8-279561

### SUMMARY OF THE INVENTION

In the conventional HBT described above, however, the ballast resistor (base ballast resistor) 116 connected to the base electrode 108 of each of the cells composing the HBT array is disposed in the transistor external region, as shown in FIG. 7B. The arrangement requires respective regions for the disposition of the ballast resistor 116 and for the disposition of an interconnect and a contact portion each connected to the ballast resistor 116 in addition to the chip area when the ballast resistor 116 is not disposed. As a result, a large increase in chip area necessitates a significant cost increase.

In the case where the base ballast resistor is disposed in the transistor external region, constraints placed by layout rules defined between the resistor including the additional interconnect and contact portion and the other patterns lower the flexibility of pattern layout.

In the case where each of a DC bias line and an RF line is connected to the base ballast resistor, the degree of suppressing a thermal runaway is increased by increasing the resistance of the base ballast resistor, while another problem of a reduction in RW power gain is encountered.

In view of the foregoing, it is therefore an object of the present invention to improve the property (e.g., RF property or the like) and reliability of a semiconductor device (e.g., RF amplifier or the like) operating in the RF band without causing a cost increase.

To attain the foregoing object, the present invention features a semiconductor device including at least one transistor having a collector layer (a subcollector layer may also be provided under the collector layer), a base layer, and an emitter layer each stacked as a carrier transit layer on a semi-insulating substrate and also having a collector electrode, a base electrode, and an emitter electrode in contact with the corresponding carrier transit layers, wherein a resistor layer is formed directly on the base electrode and an interconnect layer reaching a base terminal is extracted from the base electrode via the resistor layer. Specifically, the present invention disposes a resistor pattern directly on the base electrode in the semiconductor device operating in the RF band, i.e., disposes the resistor pattern between the interconnect layer connected to the base terminal and the base electrode and thereby improves each of the RF property and reliability of the semiconductor device.

In the semiconductor device according to the present invention, the resistor layer formed directly on the base electrode is composed of, e.g., a conductive material such as TaN, specifically a material having a high resistivity (indicating a resistivity of about 100 μΩ·cm or more which is higher than that of a metal of Au or the like used for the interconnect or the like) which is different from the materials of the base electrode and the interconnect layer. The resistor pattern composed of the resistor layer has a resistance value optimized to most effectively function as a base ballast resistor and the thickness of the resistor layer and the pattern size are determined based on the optimized resistance value.

In the semiconductor device according to the present invention, the resistor pattern composed of the resistor layer formed directly on the base electrode is formed only on the base electrode not to cause an increase in chip size.

Since the base ballast resistor in the conventional semiconductor device is disposed on the additional resistor region provided outside the transistor, respective regions for the disposition of an interconnect portion extracted from the base electrode (base extraction interconnect portion), the resistor portion, and the contact portion therebetween are required as a chip area in addition to the net HBT region.

By contrast, the present invention stacks the base electrode, the base ballast resistor, and the base extraction interconnect portion in layers so that a new increase in chip area resulting from the disposition of the base ballast resistor does not occur.

Thus, the present invention uses a structure in which the resistor pattern functioning as the base ballast resistor is formed directly on the base electrode and the interconnect layer connected to the base terminal is disposed directly on the resistor pattern and thereby allows the disposition of the base ballast resistor without causing a new increase in chip area. Accordingly, the property and reliability of the semiconductor device can be improved without entailing a cost increase.

In addition, since the present invention does not dispose the ballast resistor in the transistor external region, constraints resulting from the addition of a new pattern are not placed by the layout rules. This achieves the effect of preventing the lowering of layout flexibility even when the ballast resistor is added.

Moreover, the present invention allows the provision of another interconnect layer connected to a part of the base electrode without the intervention of the resistor layer by devising layout. Of the two types of base terminals, e.g., the interconnect layer connected to the DC bias terminal can be connected to the base electrode via the resistor layer and the interconnect layer connected to the RF input terminal can be connected directly to the base electrode. The arrangement allows reliable suppression of a thermal runaway by increasing the resistance of the resistor layer, i.e., the base ballast resistor without lowering the RF power gain. As a result, it becomes possible to provide a semiconductor device which features each of an excellent RF property and a high breakdown resistance.

Thus, the present invention relates to a semiconductor device operating in the RF band and to a method for fabricating the same. When it is applied to a HBT or the like, the present invention can improve the property and reliability thereof without causing a cost increase and is therefore extremely useful.

### BRIEF DESCRIPTION OF THE DRAWINGS

FIG. 1A is a plan view of a semiconductor device according to a first embodiment of the present invention and FIG. 1B is a cross-sectional view taken along the line A-A′ of FIG. 1A;

FIGS. 2A to 2F are cross-sectional views illustrating the individual process steps of a method for fabricating the semiconductor device according to the first embodiment;

FIG. 3 is a view showing respective variations in the resistivity and temperature 25 coefficient of a TaN film versus a N₂ partial pressure in a discharge gas during sputtering, which have been examined by the present inventors;

FIG. 4A is a plan view of a semiconductor device according to a second embodiment of the present invention and FIG. 4B is a cross-sectional view taken along the line B1-B1′ of FIG. 4A;

FIGS. 5A to 5F are cross-sectional views illustrating the individual process steps of a method for fabricating the semiconductor device according to the second embodiment;

FIGS. 6A to 6F are cross-sectional views illustrating the individual process steps of the method for fabricating the semiconductor device according to the second embodiment; and

FIG. 7A is a plan view of a conventional HBT and FIG. 7B is a cross-sectional view taken along the line C-C′ of FIG. 7A.

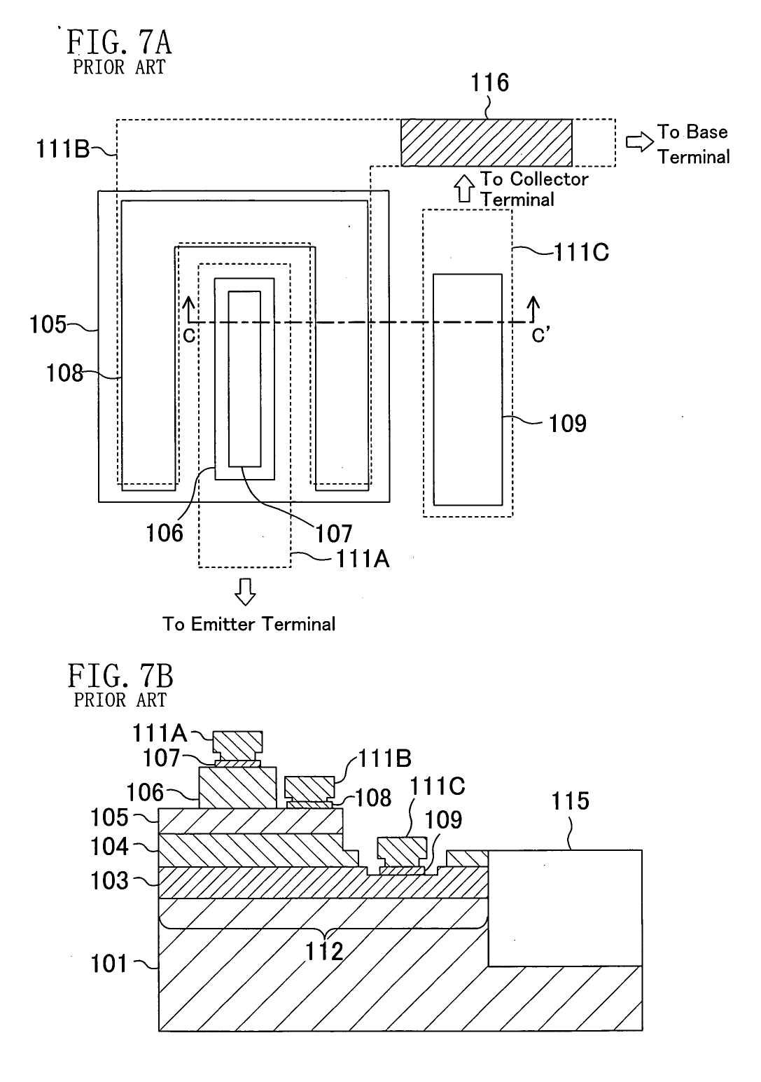

### DETAILED DESCRIPTION OF THE INVENTION

### Embodiment 1

Referring to the drawings, a semiconductor device according to a first embodiment of the present invention and a method for fabricating the same will be described herein below.

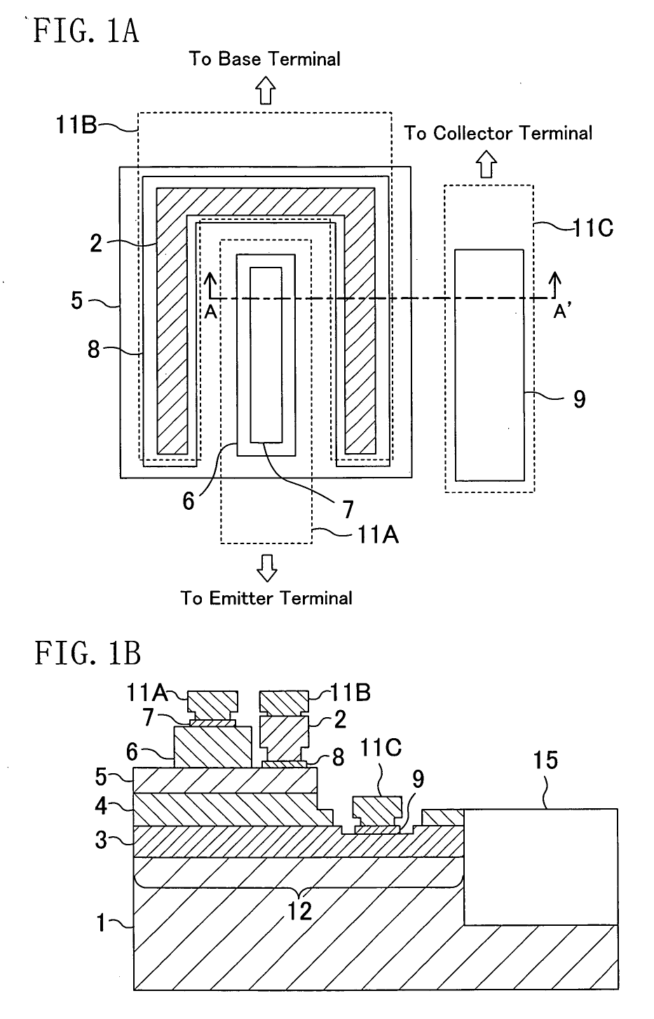

Each of FIGS. 1A and 1B shows a schematic structure of the semiconductor device (specifically a HBT) according to the first embodiment, of which FIG. 1A is a plan view thereof and FIG. 1B is a cross-sectional view taken along the line A-A′ of FIG. 1A. In FIG. 1A, some of the components are not shown.

The characteristic features of the semiconductor device according to the first embodiment are that a resistor layer is provided directly on a base electrode and that an interconnect layer electrically connected to a base terminal on the same chip is extracted directly from the upper surface of the resistor layer.

Specifically, as shown in FIG. 1B, a subcollector layer 3, a collector layer 4, a base layer 5, and an emitter layer 6 are stacked successively in an ascending order on a semi-insulating GaAs substrate 1. An emitter electrode 7 is formed on the emitter layer 6. A base electrode 8 is formed on the portion of the base layer 5 on which the emitter layer 6 is not provided. A collector electrode 9 is formed on the portion of the subcollector layer 3 on which the collector layer 4 is not provided. The individual semiconductor layers and electrodes described above constitute a HBT cell 12. The HBT cell 12 is surrounded by an isolation region 15 provided in the GaAs substrate 1.

As shown in FIGS. 1A and 1B, a metal interconnect layer 11A for providing an electric connection between the emitter electrode 7 and an emitter terminal (not shown) provided on the region (i.e., transistor external region) of the GaAs substrate 1 (i.e., on the same chip) in which the HBT cell 12 is not provided is extracted from the emitter electrode 7. In addition, a metal interconnect layer 11B for providing an electric connection between the base electrode 8 and a base terminal (not shown) provided on the transistor external region is extracted from the base electrode 8. Moreover, a metal interconnect layer 11C for providing an electric connection between the collector electrode 9 and a collector terminal (not shown) provided on the transistor external region is extracted from the collector electrode 9.

As described above, as shown in FIG. 1B, the characteristic features of the present embodiment are that the resistor layer 2 composed of, e.g., TaN is provided directly on the base electrode 8 and the metal interconnect layer 11B is extracted directly from the upper surface of the resistor layer 2. In other words, the resistor layer 2 is provided between the base electrode 8 and the metal interconnect layer 11B so that the base electrode 8 and the metal interconnect layer 11B are electrically connected to each other via the resistor layer 2.

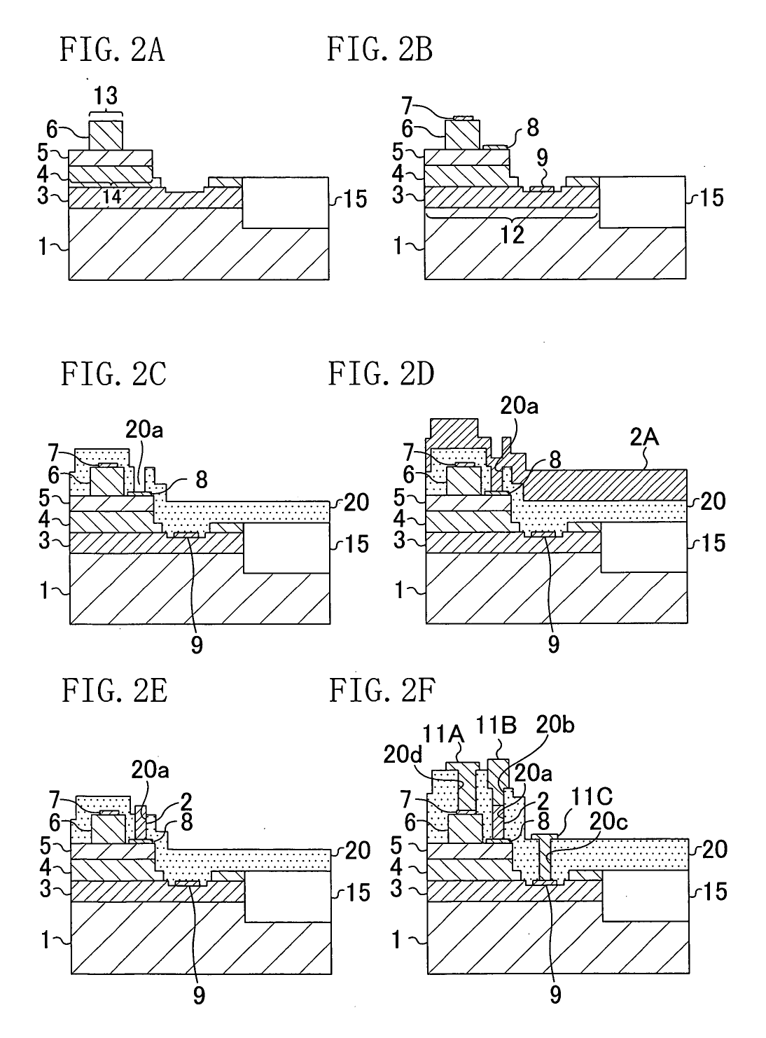

A description will be given next to a method for fabricating the semiconductor device according to the first embodiment with reference to FIGS. 2A to 2F. FIGS. 2A to 2F are cross-sectional views (corresponding to the cross-sectional structure taken along the line A-A′ of FIG. 1A) illustrating the individual process steps of the method for fabricating the semiconductor device according to the first embodiment.

First, as shown in FIG. 2A, the subcollector layer 3, the collector layer 4, the base layer 5, and the emitter layer 6 are successively grown epitaxially on a surface of the semi-insulating GaAs substrate 1. Next, the emitter layer 6 is patterned by photolithography and dry etching to form an emitter mesa 13. Subsequently, the base layer 5 and the collector layer 4 are patterned by the same method to form a base mesa 14. As a result, the base electrode formation region of the base layer 5 is exposed and the collector electrode formation region of the subcollector layer 3 is exposed. Subsequently, ion implantation is performed with respect to the GaAs substrate 1 by using a photoresist film (not shown) covering the emitter mesa 13 and the base mesa 14 as a mask, thereby forming the isolation region 15 composed of a high-resistance layer. By the isolation region 15, a transistor region is defined.

Next, as shown in FIG. 2B, the emitter electrode 7, the base electrode 8, and the collector electrode 9 are formed to come in contact with the emitter layer 6, the base layer 5 (base electrode formation region), and the subcollector layer 3 (collector electrode formation region), respectively. Then, as shown in FIG. 2C, a SiO₂ film, e.g., is formed by CVD (Chemical Vapor Deposition) as an interlayer film 20 over the entire surface of the GaAs substrate 1. Thereafter, a contact hole 20a between the base electrode and the resistor layer is formed by removing only the resistor layer formation region of the interlayer film 20 overlying the base electrode 8.

Next, as shown in FIG. 2D, a TaN film 2A serving as the resistor layer 2 is formed by, e.g., sputtering over the entire surface of the GaAs substrate 1 such that the contact hole 20a is filled with the TaN film 2A. Subsequently, a desired resist pattern (not shown) covering the resistor layer formation region (i.e., the region formed with the contact hole 20a) is formed by photolithography. Then, as shown in FIG. 2E, dry etching is performed with respect to the TaN film 2A by using the resist pattern as a mask to form the resistor layer 2 in the contact hole 20a. At this time, the resistor layer 2 has a portion thereof formed over the contact hole 20a.

Next, as shown in FIG. 2F, a SiO₂ film, e.g., serving as the interlayer film 20 is formed by CVD over the entire surface of the GaAs substrate 1, thereby covering the resistor layer 2 with the interlayer film 20. Thereafter, a contact hole 20b between the resistor layer and a first interconnect layer which reaches the resistor layer 2, a contact hole 20c between the collector electrode and the first interconnect layer which reaches the collector electrode 9, and a contact hole 20d between the emitter electrode and the first interconnect layer which reaches the emitter electrode 7 are formed in the interlayer film 20 by, e.g., photolithography and dry etching. Then, an Au film is formed by, e.g., vapor deposition over the entire surface of the GaAs substrate 1 and patterned to form the metal interconnect layer (first interconnect layer) 11A connected to the emitter electrode 7 through the contact hole 20d, the metal interconnect layer (first interconnect layer) 11B connected to the resistor layer 2 through the contact hole 20b, and the metal interconnect layer (first interconnect layer) 11C connected to the collector electrode 9 through the contact hole 20c.

Thereafter, a SiN film serving as an interlayer film is formed by, e.g., CVD over the entire surface of the GaAs substrate 1 and contact holes between the first interconnect layer and a second interconnect layer are formed in the necessary portions thereof, though the depiction thereof is omitted. Then, an Au film is deposited by, e.g., electrolytic plating over the entire surface of the GaAs substrate 1 to fill in the holes and patterned to form the

In the present embodiment, the collector electrode 9, the emitter electrode 7, and the resistor layer 2 formed directly on the base electrode 8 are electrically connected to the collector terminal, the emitter terminal, and the base terminal each located on the transistor external region via the first and second interconnect layers and via the contact between the first and second interconnect layers.

As described above, the present embodiment uses a structure in which the resistor layer 2 functioning as the base ballast resistor is formed directly on the base electrode 8 and the interconnect layer 11B connected to the base terminal is extracted directly from the upper surface of the resistor layer 2. This allows the base ballast resistor to be disposed without newly increasing the chip area. In other words, the chip area remains the same irrespective of the presence or absence of the base ballast resistor. Accordingly, the property and reliability of the semiconductor device can be improved without entailing a cost increase.

Since the present embodiment does not dispose the ballast resistor in the transistor external region, constraints resulting from the addition of a new pattern are not placed by layout rules. This achieves the effect of preventing the lowering of layout flexibility even when the ballast resistor is added.

In addition, the present embodiment deposits the TaN film serving as the base ballast resistor, i.e., the resistor layer 2 by sputtering. As a result, even when the resistor layer 2 is formed in a limited range over the base electrode 8, the resistance of the resistor layer 2 can be set to a desired value by, e.g., optimizing a N₂ partial pressure in a discharge gas during sputtering.

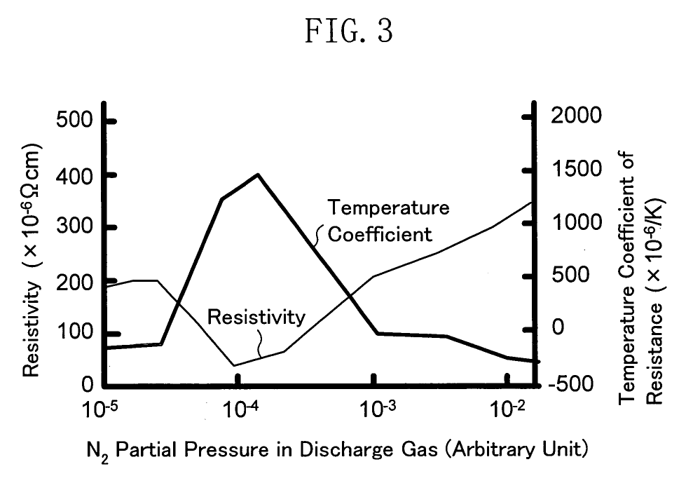

Specifically, a condition when the resistor layer 2 is formed by sputtering, e.g., the N₂ partial pressure in the discharge gas is optimized such that a desired resistivity and a desired temperature coefficient are obtainable for the sputtered film serving as the resistor layer 2. A ballast resistance value and the temperature coefficient of the resistance which are required of the resistor layer 2 are realized by using the optimized condition and adjusting the size and thickness of the resistor pattern based thereon. FIG. 3 shows respective variations in the resistivity and temperature coefficient of the TaN film versus the N₂ partial pressure in the discharge gas during sputtering. As shown in FIG. 3, the resistivity and temperature coefficient of the TaN film in a desired combination can be obtained by controlling the N₂ partial pressure in the discharge gas.

The first embodiment can achieve the same effects even when it is applied to each of HBT cells composing a HBT array or to a single HBT. The same effects are also achievable even when the first embodiment is applied to another device structure in which a ballast resistor is disposed other than a HBT.

The first embodiment has formed the collector electrode 9 on the portion of the subcollector layer 3 in which the collector layer 4 is not provided. However, it is also possible to implement a contact between the collector electrode 9 and the subcollector layer 3 by forming the collector electrode 9 on the collector layer 4 without exposing the collector electrode formation region of the subcollector layer 3 and diffusing a material for composing the collector electrode 9 in the collector layer 4.

In the first embodiment, the subcollector layer 3 need not necessarily be provided. That is, it is also possible to stack the collector layer 4, the base layer 5, and the emitter layer 6 in an ascending order on the GaAs substrate 1, pattern the base layer 5 and the emitter layer 6 to expose the base electrode formation region of the base layer 5 and expose the collector electrode formation region of the collector layer 4, and then form the emitter electrode 7, the base electrode 8, and the collector electrode 9 on the emitter layer 6, the base electrode formation region of the base layer 5, and the collector electrode formation region of the collector layer 4, respectively.

Although the first embodiment has used TaN as the material of the resistor layer 2, it is not limited thereto. It is also possible to use a material different from the respective materials of the base electrode 8 and the interconnect layer 11, specifically a material having a higher resistivity than the respective materials of the base electrode 8 and the interconnect layer 11 such as a material containing at least one of a nitride, a carbide, and an oxide. The arrangement allows a high resistance to be obtained with a small area even when device miniaturization proceeds or the use of an MMIC (Microwave Monolithic Integrated Circuit) is promoted and also allows easy processing of the resistor layer 2 by dry etching or wet etching.

In the first embodiment, the resistance of the material of the resistor layer 2 preferably has a positive temperature coefficient. In the arrangement, the resistance of the resistor layer 2 increases as the junction temperature increases so that an emitter-to-base current is reduced. As a result, an amount of heat generation decreases and an increase in junction temperature is suppressed. In other words, the breakdown of the device caused by the negative correlation between the emitter-to-base current and the junction temperature can be prevented.

In the first embodiment, the resistor layer 2 formed directly on the base electrode 8, i.e., the resistor pattern is preferably formed only on the base electrode 8 to prevent an increase in chip size.

### Embodiment 2

Referring to the drawings, a semiconductor device according to a second embodiment of the present invention and a method for fabricating the same will be described herein below.

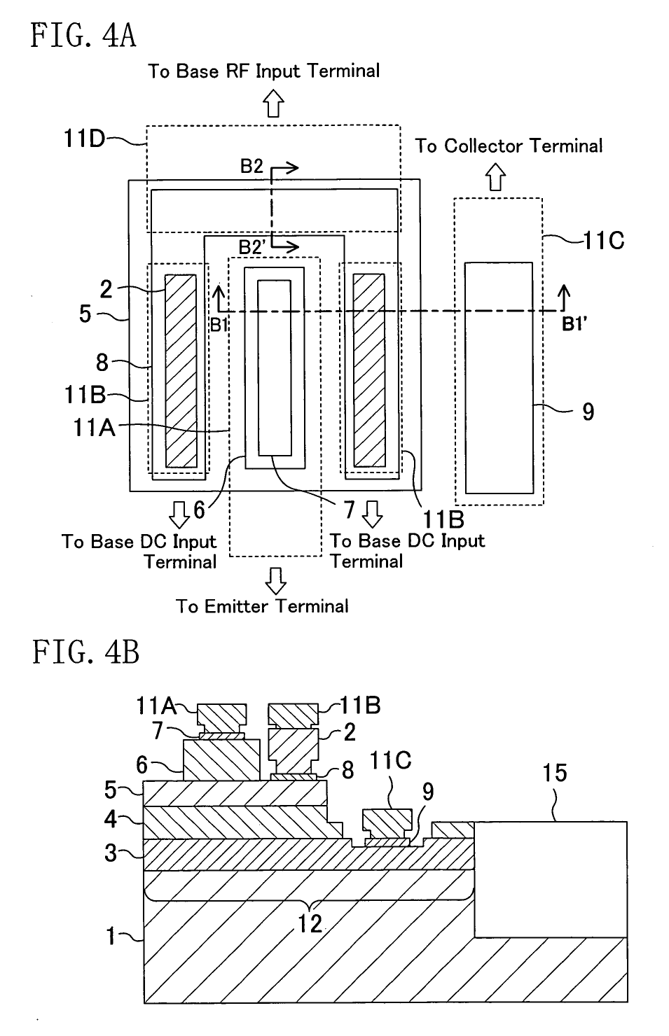

Each of FIGS. 4A and 4B shows a schematic structure of the semiconductor device (specifically a HBT) according to the second embodiment, of which FIG. 4A is a plan view thereof and FIG. 4B is a cross-sectional view taken along the line B1-B1′ of FIG. 4A. In FIG. 4A, some of the components are not shown.

The characteristic features of the second embodiment are that a resistor layer is provided directly on a specified portion of the base electrode, that an interconnect layer electrically connected to a base DC input terminal on the same chip is extracted directly from the upper surface of the resistor layer, and that an interconnect layer electrically connected to a base RF input terminal on the same chip is extracted directly from another portion of the upper surface of the base electrode other than the specified portion thereof without the intervention of the resistor layer.

Specifically, as shown in FIG. 4B, a subcollector layer 3, a collector layer 4, a base layer 5, and an emitter layer 6 are stacked successively in an ascending order on a semi-insulating GaAs substrate 1. An emitter electrode 7 is formed on the emitter layer 6. A base electrode 8 is formed on the portion of the base layer 5 on which the emitter layer 6 is not provided. A collector electrode 9 is formed on the portion of the subcollector layer 3 on which the collector layer 4 is not provided. The individual semiconductor layers and electrodes described above constitute a HBT cell 12. The HBT cell 12 is surrounded by an isolation region 15 provided in the GaAs substrate 1.

As shown in FIGS. 4A and 4B, a metal interconnect layer 11A for providing an electric connection between the emitter electrode 7 and an emitter terminal (not shown) provided on the region (i.e., transistor external region) of the GaAs substrate 1 (i.e., on the same chip) in which the HBT cell 12 is not provided is extracted from the emitter electrode 7. In addition, a metal interconnect layer 11B for providing an electric connection between the base electrode 8 and a base DC input terminal (not shown) provided on the transistor external region is extracted from a portion of the base electrode 8, while a metal interconnect layer 11D for providing an electric connection between the base electrode 8 and a base RF input terminal (not shown) provided on the transistor external region is extracted from another portion of the base electrode 8. Moreover, a metal interconnect layer 11C for providing an electric connection between the collector electrode 9 and a collector terminal (not shown) provided on the transistor external region is extracted from the collector electrode 9.

As described above, the characteristic features of the present embodiment are that the resistor layer 2 composed of, e.g., TaN is provided directly on the specified portion of the base electrode 8 and the metal interconnect layer 11B electrically connect to the base DC input terminal is extracted directly from the upper surface of the resistor layer 2, as shown in FIG. 4B. In other words, the resistor layer 2 is provided between the base electrode 8 and the metal interconnect layer 11B so that the base electrode 8 and the metal interconnect layer 11B are electrically connected to each other via the resistor layer 2. On the other hand, the metal interconnect layer 11D electrically connected to the base RF input terminal is extracted directly from another portion of the upper surface of the base electrode 8 other than the specified portion without the intervention of the resistor layer 2, as shown in FIG. 4A.

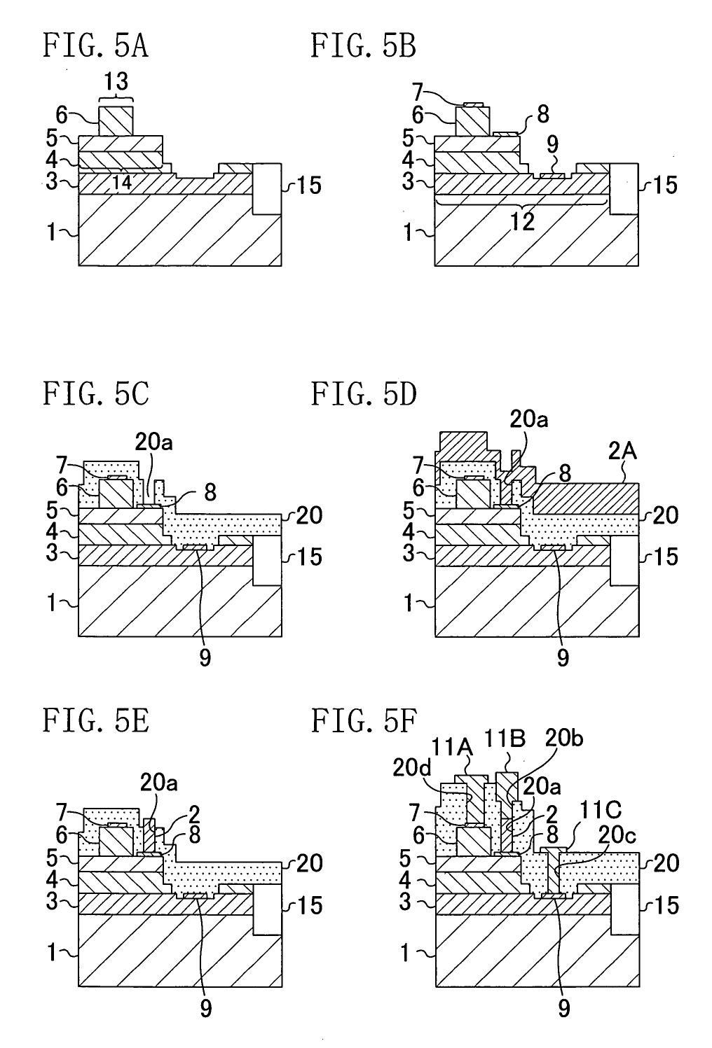

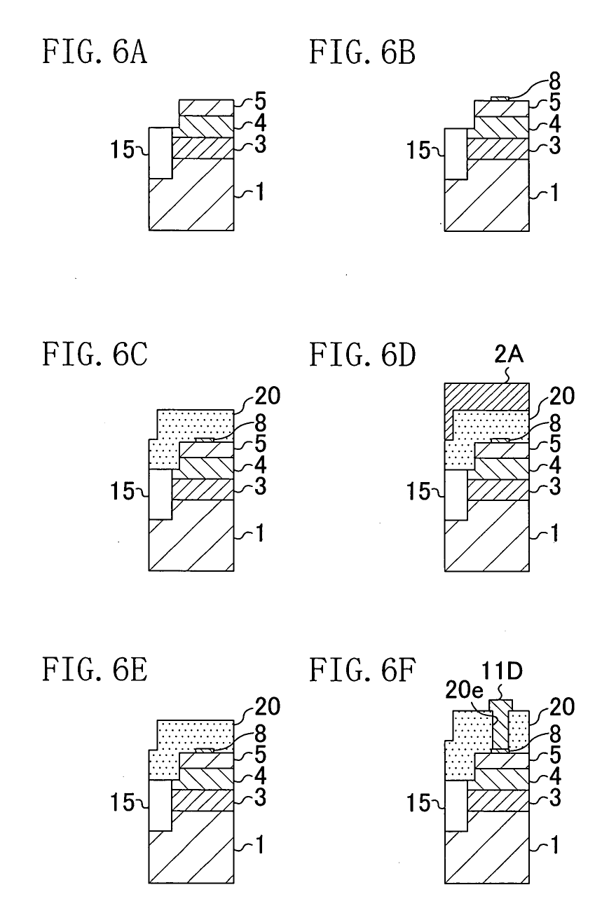

A description will be given next to a method for fabricating the semiconductor device according to the second embodiment with reference to FIGS. 5A to 5F and FIGS. 6A to 6F. FIGS. 5A to 5F and FIGS. 6A to 6F are cross-sectional views illustrating the individual process steps of the method for fabricating the semiconductor device according to the second embodiment. FIGS. 5A to 5F correspond to the cross-sectional structure taken along the line B1-B1′ of FIG. 4A. FIGS. 6A to 6F correspond to the cross-sectional structure taken along the line B2-B2′ of FIG. 4A.

First, as shown in FIGS. 5A and 6A, the subcollector layer 3, the collector layer 4, the base layer 5, and the emitter layer 6 are successively grown epitaxially on a surface of the semi-insulating GaAs substrate 1. Next, the emitter layer 6 is patterned by photolithography and dry etching to form an emitter mesa 13. Subsequently, the base layer 5 and the collector layer 4 are patterned by the same method to form a base mesa 14. As a result, the base electrode formation region of the base layer 5 is exposed and the collector electrode formation region of the subcollector layer 3 is exposed. Subsequently, ion implantation is performed with respect to the GaAs substrate 1 by using a photoresist film (not shown) covering the emitter mesa 13 and the base mesa 14 as a mask, thereby forming the isolation region 15 composed of a high-resistance layer. By the isolation region 15, a transistor region is defined.

Next, as shown in FIGS. 5B and 6B, the emitter electrode 7, the base electrode 8, and the collector layer 9 are formed to come in contact with the emitter layer 6, the base layer 5 (base electrode formation region), and the subcollector layer 3 (collector electrode formation region), respectively. Then, as shown in FIG. 5C and 6C, a SiO₂ film, e.g., is formed by CVD as an interlayer film 20 over the entire surface of the GaAs substrate 1. Thereafter, a contact hole 20A between the base electrode and the resistor layer is formed by removing only the resistor layer formation region of the interlayer film 20 overlying the base electrode 8.

Next, as shown in FIGS. 5D and 6D, a TaN film 2A serving as the resistor layer 2 is formed by, e.g., sputtering over the entire surface of the GaAs substrate 1 such that the contact hole 20a is filled with the TaN film 2A. Subsequently, a desired resist pattern (not shown) covering a resistor layer formation region (i.e., the region formed with the contact hole 20a) is formed by photolithography. Then, as shown in FIGS. 5E and 6E, dry etching is performed with respect to the TaN film 2A by using the resist pattern as a mask to form the resistor layer 2 in the contact hole 20a. At this time, the resistor layer 2 has a portion thereof formed over the contact hole 20a.

Next, as shown in FIGS. 5F and 6F, a SiO₂ film, e.g., serving as the interlayer film 20 is formed by CVD over the entire surface of the GaAs substrate 1, thereby covering the resistor layer 2 with the interlayer film 20. Thereafter, a contact hole 20b between the resistor layer and a first interconnect layer (first interconnect layer electrically connected to the base DC input terminal) which reaches the resistor layer 2, a contact hole 20c between the collector electrode and the first interconnect layer which reaches the collector electrode 9, a contact hole 20d between the emitter electrode and the first interconnect layer which reaches the emitter electrode 7, and a contact hole 20e between the base electrode and a first interconnect layer (first interconnect layer electrically connected to the base RF input terminal) which reaches the base electrode 8 (the portion thereof on which the resistor layer 2 is not formed) are formed in the interlayer film 20 by, e.g., photolithography and dry etching. Then, an Au film is formed by, e.g., vapor deposition over the entire surface of the GaAs substrate 1 and patterned to form the metal interconnect layer (first interconnect layer) 11A connected to the emitter electrode 7 through the contact hole 20d, the metal interconnect layer (first interconnect layer) 11B connected to the resistor layer 2 through the contact hole 20b, the metal interconnect layer (first interconnect layer) 11C connected to the collector electrode 9 through the contact hole 20c, and the metal interconnect layer (first interconnect layer) 11D connected directly to the base electrode 8 through the contact hole 20e.

Thereafter, a SiN film serving as an interlayer film is formed by, e.g., CVD over the entire surface of the GaAs substrate 1 and contact holes between the first interconnect layer and a second interconnect layer are formed in the necessary portions thereof, though the depiction thereof is omitted. Then, an Au film is deposited by, e.g., electrolytic plating over the entire surface of the GaAs substrate 1 to fill in the holes and patterned to form the second interconnect layer.

In the present embodiment, the collector electrode 9, the emitter electrode 7, the resistor layer 2 formed directly on the specified portion of the base electrode 8, and another portion of the base electrode 8 are electrically connected to the collector terminal, the emitter terminal, the base DC input terminal, and the base RF input terminal each located on the transistor external region via the first and second interconnect layers and via the contact between the first and second interconnect layers.

Thus, according to the present embodiment, the interconnect layer 11B connected to the base DC input terminal is extracted directly from the upper surface of the resistor layer 2 functioning as the base ballast resistor and formed directly on only one portion of the base electrode 8, while the interconnect layer 11D connected to the base RF input terminal is extracted directly from another portion of the base electrode 8. As a result, a DC bias current passes through the resistor layer 2, thereby allowing potential control using the ballast resistor. On the other hand, an RF input does not pass through the resistor layer 2, i.e., the ballast resistor, thereby allowing the prevention of the occurrence of a current loss and the degradation of the RF property. In other words, a thermal runaway can be suppressed reliably by increasing the resistance of the resistor layer 2, i.e., the base ballast resistor without lowering an RF power gain. According, it becomes possible to obtain a semiconductor device featuring each of an excellent RF property and a high breakdown resistance.

In addition, the present embodiment uses a structure in which the resistor layer 2 functioning as a base ballast resistor is formed directly on the base electrode 8 and the interconnect layer 11B connected to the base terminal is extracted directly from the upper surface of the resistor layer 2. This allows the base ballast resistor to be disposed without newly increasing the chip area. In other words, the chip area remains the same irrespective of the presence or absence of the base ballast resistor. Accordingly, the property and reliability of the semiconductor device can be improved without entailing a cost increase.

Since the present embodiment does not dispose the ballast resistor in the transistor external region, constraints resulting from the addition of a new pattern are not placed by layout rules. This achieves the effect of preventing the lowering of layout flexibility even when the ballast resistor is added.

Moreover, the present embodiment deposits the TaN film serving as the base ballast resistor, i.e., the resistor layer 2 by sputtering. As a result, even when the resistor layer 2 is formed in a limited range over the base electrode 8, the resistance of the resistor layer 2 can be set to a desired value by, e.g., optimizing a N₂ partial pressure in a discharge gas during sputtering. Specifically, a condition when the resistor layer 2 is formed by sputtering, e.g., the N₂ partial pressure in the discharge gas is optimized such that a desired resistivity and a desired temperature coefficient are obtainable for the sputtered film serving as the resistor layer 2. A ballast resistance value and the temperature coefficient of the resistance which are required of the resistor layer 2 are realized by using the optimized condition and adjusting the size and thickness of the resistor pattern based thereon.

The second embodiment can achieve the same effects even when it is applied to each of HBT cells composing a HBT array or to a single HBT. The same effects are also achievable even when the second embodiment is applied to another device structure in which a ballast resistor is disposed other than a HBT.

The second embodiment has formed the collector electrode 9 on the portion of the subcollector layer 3 in which the collector layer 4 is not provided. However, it is also possible to implement a contact between the collector electrode 9 and the subcollector layer 3 by forming the collector electrode 9 on the collector layer 4 without exposing the collector electrode formation region of the subcollector layer 3 and diffusing a material for composing the collector electrode 9 in the collector layer 4.

In the second embodiment, the subcollector layer 3 need not necessarily be provided. That is, it is also possible to stack the collector layer 4, the base layer 5, and the emitter layer 6 in an ascending order on the GaAs substrate 1, pattern the base layer 5 and the emitter layer 6 to expose the base electrode formation region of the base layer 5 and expose the collector electrode formation region of the collector layer 4, and then form the emitter electrode 7, the base electrode 8, and the collector electrode 9 on the emitter layer 6, the base electrode formation region of the base layer 5, and the collector electrode formation region of the collector layer 4, respectively.

Although the second embodiment has used TaN as the material of the resistor layer 2, it is not limited thereto. It is also possible to use a material different from the respective materials of the base electrode 8 and the interconnect layer 11, specifically a material having a higher resistivity than the respective materials of the base electrode 8 and the interconnect layer 11 such as a material containing at least one of a nitride, a carbide, and an oxide. The arrangement allows a high resistance to be obtained with a small area even when device miniaturization proceeds or the use of an MMIC is promoted and also allows easy processing of the resistor layer 2 by dry etching or wet etching.

In the second embodiment, the resistance of the material of the resistor layer 2 preferably has a positive temperature coefficient. In the arrangement, the resistance of the resistor layer 2 increases as the junction temperature increases so that an emitter-to-base current is reduced. As a result, an amount of heat generation decreases and an increase in junction temperature is suppressed. In other words, the breakdown of the device caused by the negative correlation between the emitter-to-base current and the junction temperature can be prevented.

In the second embodiment, the resistor layer 2 formed immediately on the base electrode 8, i.e., the resistor pattern is preferably formed only on the base electrode 8 to prevent an increase in chip size.

Although the second embodiment has used the interconnect layer 11B electrically connected to the base electrode 8 via the resistor layer 2 for connection with the base DC input terminal and used the interconnect layer 11D connected directly to the base electrode 8 without the intervention of the resistor layer 2 for connection with the base RF input terminal, it will easily be appreciated that the applications of the interconnect layers connected electrically to the base electrode 8 are not particularly limited.

What is claimed is:

1. A semiconductor device comprising:
at least one transistor having a subcollector layer formed on a semi-insulating substrate, a collector layer formed on a specified portion of the subcollector layer, a base layer formed on the collector layer, an emitter layer formed on a specified portion of the base layer, an emitter electrode formed on the emitter layer, a base electrode formed on a portion of the base layer on which the emitter layer is not provided, and a collector electrode formed on a portion of the subcollector layer on which the collector layer is not provided, the semiconductor device further comprising:
an interconnect layer for providing an electric connection between the base electrode and a base terminal provided on a region of the semi-insulating substrate in which the transistor is not formed, wherein
a resistor layer composed of a material different from respective materials composing the base electrode and the interconnect layer is formed on the base electrode and the base electrode and the interconnect layer are connected to each other via the resistor layer.

2. The semiconductor device of claim 1, wherein the resistor layer contains at least one of a nitride, a carbide, and an oxide.

3. The semiconductor device of claim 1, wherein a resistance of the material composing the resistor layer has a positive temperature coefficient.

4. The semiconductor device of claim 1, wherein the transistor is a heterojunction bipolar transistor.

5. A semiconductor device comprising:
at least one transistor having a collector layer formed on a semi-insulating substrate, a base layer formed on the collector layer, an emitter layer formed on a specified portion of the base layer, an emitter electrode formed on the emitter layer, a base electrode formed on a portion of the base layer on which the emitter layer is not provided, and a collector electrode formed on a portion of the collector layer on which the base layer is not provided, the semiconductor device further comprising:
an interconnect layer for providing an electric connection between the base electrode and a base terminal provided on a region of the semi-insulating substrate on which the transistor is not formed, wherein
a resistor layer composed of a material different from respective materials composing the base electrode and the interconnect layer is formed on the base electrode and the base electrode and the interconnect layer are connected to each other via the resistor layer.

6. The semiconductor device of claim 5, wherein the resistor layer contains at least one of a nitride, a carbide, and an oxide.

7. The semiconductor device of claim 5, wherein a resistance of the material composing the resistor layer has a positive temperature coefficient.

8. The semiconductor device of claim 5, wherein the transistor is a heterojunction bipolar transistor.

9. A method for fabricating a semiconductor device, the method comprising the steps of:
successively forming a subcollector layer, a collector layer, a base layer, and an emitter layer on a semi-insulating substrate;
patterning each of the emitter layer, the base layer, and the collector layer to expose a base electrode formation region of the base layer and expose a collector electrode formation region of the subcollector layer;
forming an emitter electrode on the emitter layer;
forming a base electrode on the base electrode formation region of the base layer;
forming a collector electrode on the collector electrode formation region of the subcollector layer; and
forming an interconnect layer for providing an electric connection between the base electrode and a base terminal provided on a transistor external region of the semi-insulating substrate, the method further comprising the step of:
prior to the step of forming the interconnect layer, forming a resistor layer composed of a material different from respective materials composing the base electrode and the interconnect layer on the base electrode, wherein
the base electrode and the interconnect layer are connected to each other via the resistor layer.

10. The method of claim 9, wherein the step of forming the resistor layer includes forming a film containing at least one of a nitride, a carbide, and an oxide by sputtering and patterning the film into the resistor layer.

11. A method for fabricating a semiconductor device, the method comprising the steps of:
successively forming a collector layer, a base layer, and an emitter layer on a semi-insulating substrate;
patterning each of the emitter layer and the base layer to expose a base electrode formation region of the base layer and expose a collector electrode formation region of the collector layer;
forming an emitter electrode on the emitter layer;
forming a base electrode on the base electrode formation region of the base layer;
forming a collector electrode on the collector electrode formation region of the collector layer; and
forming an interconnect layer for providing an electric connection between the base electrode and a base terminal provided on a transistor external region of the semi-insulating substrate, the method further comprising the step of:
prior to the step of forming the interconnect layer, forming a resistor layer composed of a material different from respective materials composing the base electrode and the interconnect layer on the base electrode, wherein
the base electrode and the interconnect layer are connected to each other via the resistor layer.

12. The method of claim 11, wherein the step of forming the resistor layer includes forming a film containing at least one of a nitride, a carbide, and an oxide by sputtering and patterning the film into the resistor layer.
